(19) United States
(12) Patent Application Publication
(10) Pub. No.: US 2024/0030178 A1
(43) Pub. Date: Jan. 25, 2024

(54) SEMICONDUCTOR DEVICE AND MANUFACTURING METHOD FOR SEMICONDUCTOR DEVICE

(71) Applicant: ROHM CO., LTD., Kyoto-shi (JP)

(72) Inventors: Yosui FUTAMURA, Kyoto-shi (JP); Shunya MIKAMI, Kyoto-shi (JP)

(21) Appl. No.: 18/478,122

(22) Filed: Sep. 29, 2023

Related U.S. Application Data
(63) Continuation of application No. PCT/JP2022/011312, filed on Mar. 14, 2022.

(30) Foreign Application Priority Data
Apr. 1, 2021 (JP) 2021-062894

(51) Int. Cl. H01L 23/00; H01L 23/495

(52) U.S. Cl. CPC H01L 24/48; H01L 24/85; H01L 23/4952; H01L 23/49503; H01L 23/49562; H01L 2224/48465; H01L 2224/85051; H01L 2924/13091; H01L 2224/85181

(57) ABSTRACT

A semiconductor device includes a semiconductor element, a first lead, a second lead, and a first wire. The bonding-pad reverse surface is offset from the die-pad reverse surface toward the die-pad obverse surface-side in the z direction. The first wire is bonded to the first electrode and the bonding-pad obverse surface. The bonding pad portion includes a single first portion. The first portion is connected to the bonding-pad reverse surface, is surrounded by the bonding-pad reverse surface as viewed in the z direction, and includes a part present at a position different from the bonding-pad reverse surface in the z direction.

### TECHNICAL FIELD

The present disclosure relates to a semiconductor device and a method for manufacturing a semiconductor device.

### BACKGROUND ART

An example of conventional semiconductor device is disclosed in JP-A-2018-113359. The semiconductor device disclosed in JP-A-2018-113359 includes a first lead, a semiconductor element mounted on an island portion of the first lead, a second lead, and a wire. The wire is bonded to an obverse surface electrode of the semiconductor element and a wire bonding pad of the second lead. The wire bonding pad of the second lead is located above the island portion of the first lead.

### BRIEF DESCRIPTION OF THE DRAWINGS

FIG. 1 is a plan view of a semiconductor device according to a first embodiment of the present disclosure.

FIG. 2 is a plan view showing main parts of the semiconductor device according to the first embodiment of the present disclosure.

FIG. 3 is a bottom view showing main parts of the semiconductor device according to the first embodiment of the present disclosure.

FIG. 4 is a front view of the semiconductor device according to the first embodiment of the present disclosure.

FIG. 5 is a side view of the semiconductor device according to the first embodiment of the present disclosure.

FIG. 6 is a sectional view taken along line VI-VI in FIG. 2.

FIG. 7 is a sectional view taken along line VII-VII in FIG. 2.

FIG. 8 is an enlarged sectional view showing a main part of the semiconductor device according to the first embodiment of the present disclosure.

FIG. 9 is an enlarged bottom view showing a main part of the semiconductor device according to the first embodiment of the present disclosure.

FIG. 10 is an enlarged sectional view showing a main part of the semiconductor device according to the first embodiment of the present disclosure.

FIG. 11 is an enlarged bottom view showing a main part of the semiconductor device according to the first embodiment of the present disclosure.

FIG. 12 is a plan view of main parts for showing a method for manufacturing the semiconductor device according to the first embodiment of the present disclosure.

FIG. 13 is a sectional view taken along line XIII-XIII in FIG. 12.

FIG. 14 is an enlarged sectional view of a main part for showing the method for manufacturing the semiconductor device according to the first embodiment of the present disclosure.

FIG. 15 is an enlarged sectional view of a main part for showing the method for manufacturing the semiconductor device according to the first embodiment of the present disclosure.

FIG. 16 is a plan view of main parts for showing the method for manufacturing the semiconductor device according to the first embodiment of the present disclosure.

FIG. 17 is a sectional view taken along line XVII-XVII in FIG. 16.

FIG. 18 is a sectional view for showing the method for manufacturing the semiconductor device according to the first embodiment of the present disclosure.

FIG. 19 is a sectional view for showing the method for manufacturing the semiconductor device according to the first embodiment of the present disclosure.

FIG. 20 is an enlarged sectional view of a main part for showing the method for manufacturing the semiconductor device according to the first embodiment of the present disclosure.

FIG. 21 is an enlarged sectional view of a main part for showing the method for manufacturing the semiconductor device according to the first embodiment of the present disclosure.

FIG. 22 is a plan view of main parts for showing the method for manufacturing the semiconductor device according to the first embodiment of the present disclosure.

FIG. 23 is a sectional view taken along line XXIII-XXIII in FIG. 22.

FIG. 24 is an enlarged sectional view of a main part for showing a variation of the method for manufacturing the semiconductor device according to the first embodiment of the present disclosure.

FIG. 25 is an enlarged bottom view of a main part for showing a variation of the semiconductor device according to the first embodiment of the present disclosure.

FIG. 26 is an enlarged bottom view of a main part for showing a variation of the semiconductor device according to the first embodiment of the present disclosure.

FIG. 27 is an enlarged bottom view of a main part for showing a variation of the semiconductor device according to the first embodiment of the present disclosure.

FIG. 28 is an enlarged sectional view of a main part for showing a method for manufacturing a semiconductor device according to a variation of the first embodiment of the present disclosure.

FIG. 29 is an enlarged bottom view of a main part for showing a variation of the semiconductor device according to the first embodiment of the present disclosure.

FIG. 30 is an enlarged sectional view of a main part for showing a variation of the semiconductor device according to the first embodiment of the present disclosure.

FIG. 31 is an enlarged sectional view of a main part for showing a variation of the semiconductor device according to the first embodiment of the present disclosure.

FIG. 32 is a sectional view of a semiconductor device according to a second embodiment of the present disclosure.

FIG. 33 is a sectional view showing a method for manufacturing the semiconductor device according to the second embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

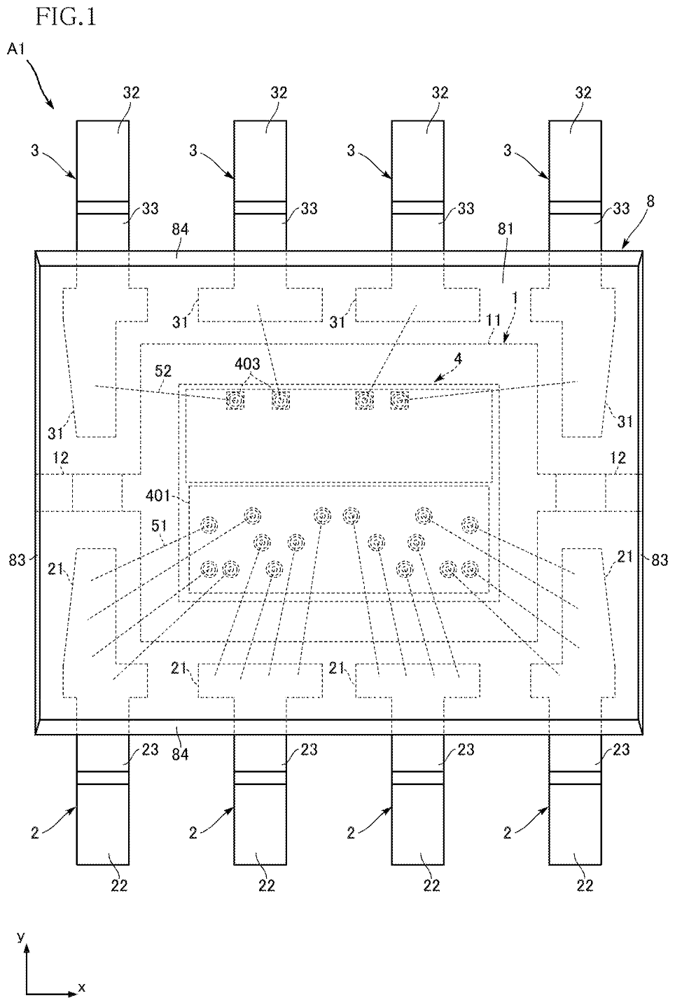

FIGS. 1 to 8 show a semiconductor device A1 according to a first embodiment of the present disclosure. The semiconductor device A1 of the present embodiment includes a first lead 1, a plurality of second leads 2, a plurality of third leads 3, a semiconductor element 4, a plurality of first wires 51, a plurality of second wires 52, and a sealing resin 8. The shape and size of the semiconductor device A1 is not particularly limited. As one example of the size of the semiconductor device A1, the dimension in x direction may be about 4 to 7 mm, the dimension in y direction may be about 4 to 8 mm, and the dimension in z direction may be about 0.7 to 2.0 mm.

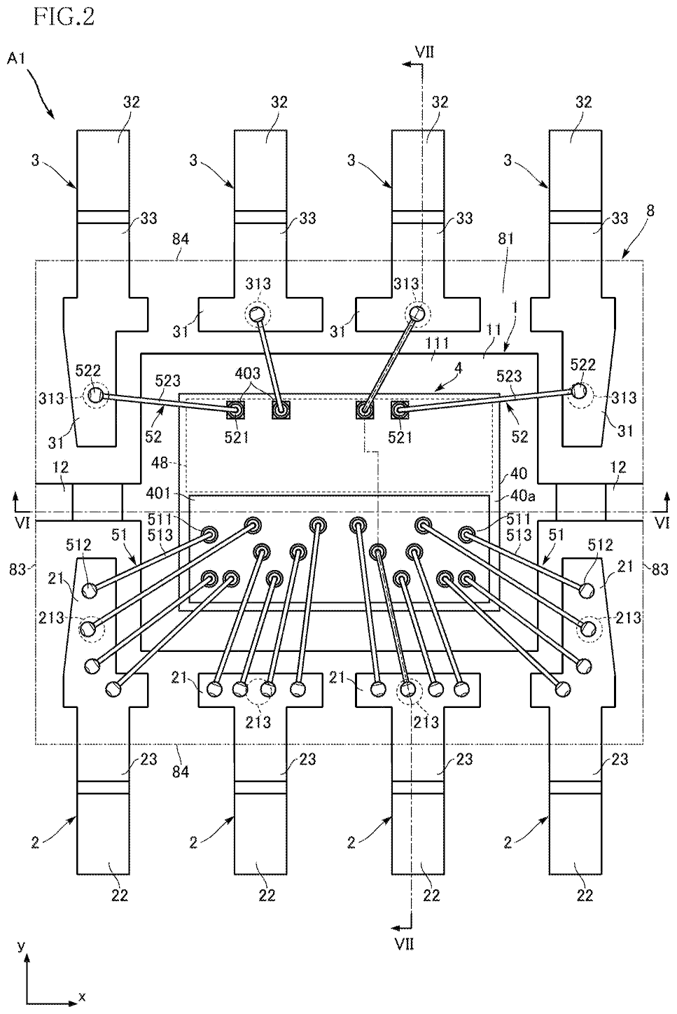

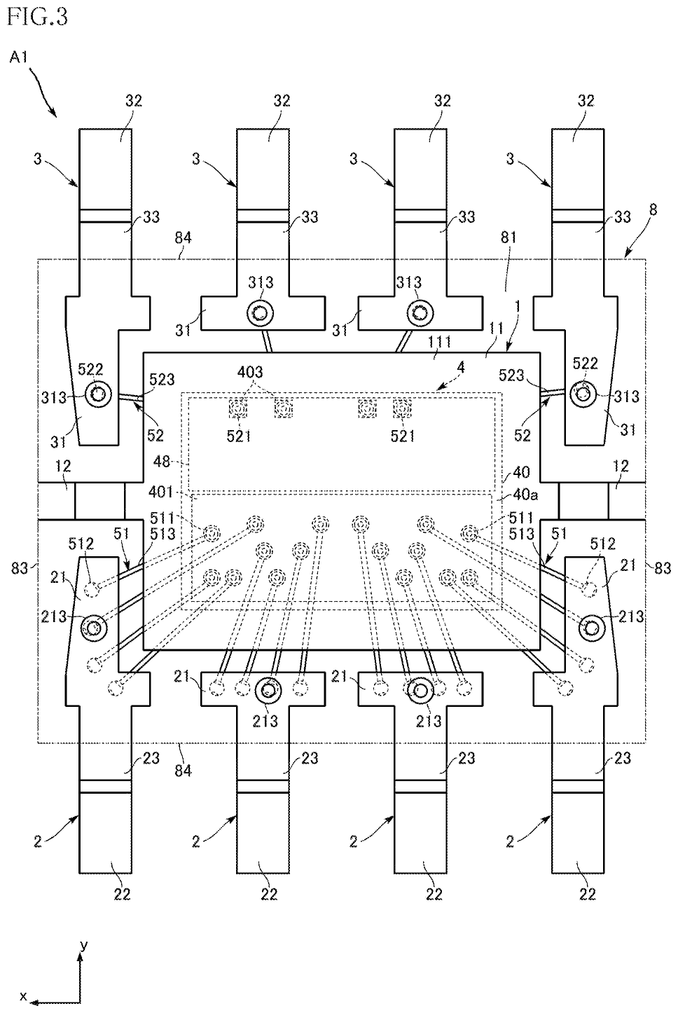

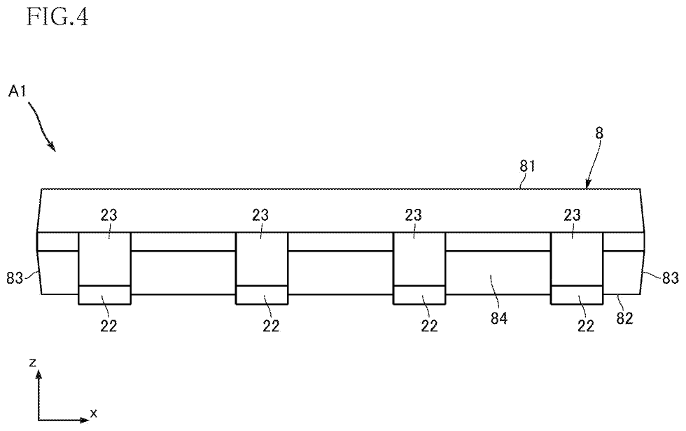

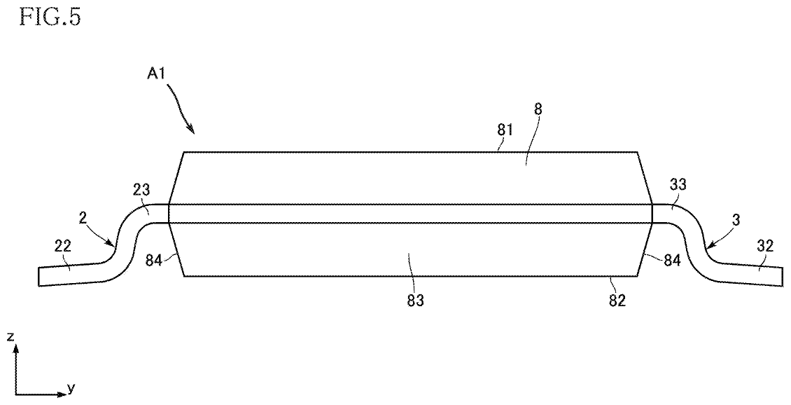

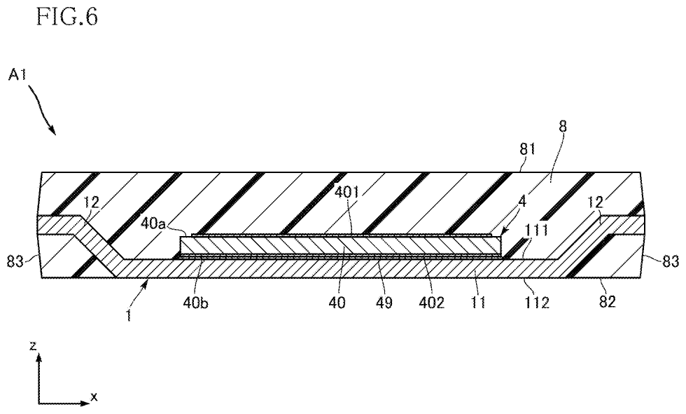

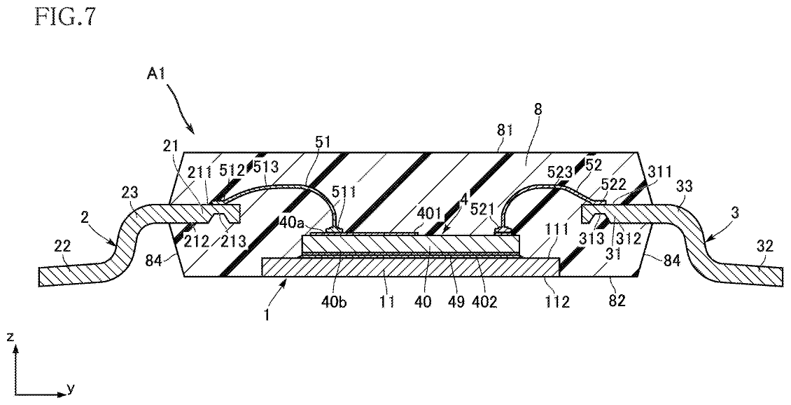

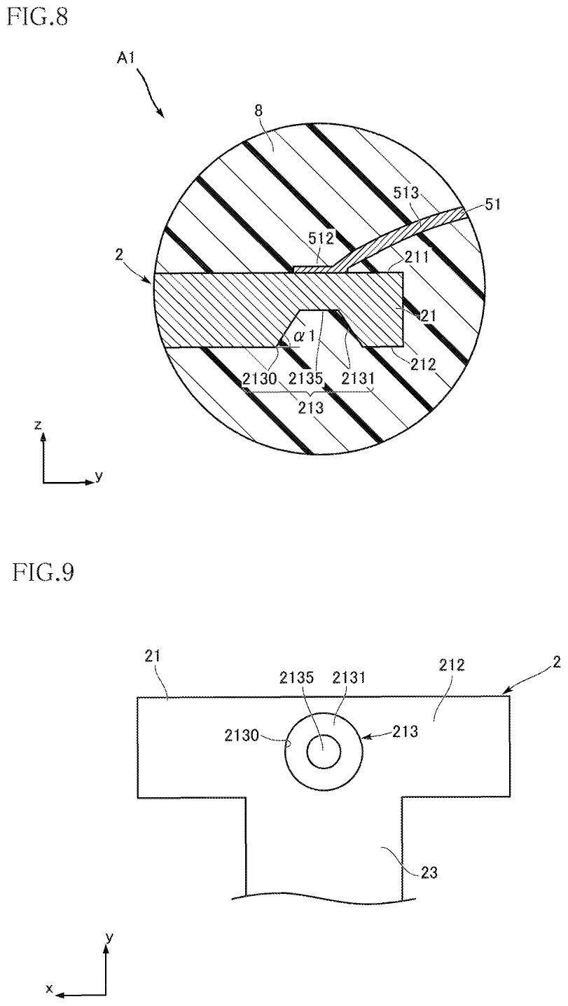

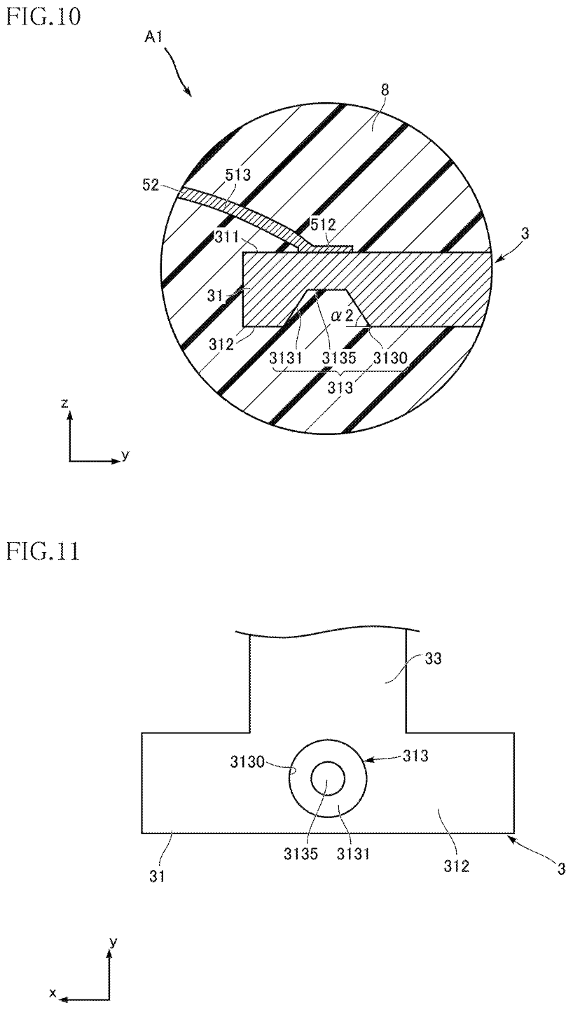

FIG. 1 is a plan view of the semiconductor device A1. FIG. 2 is a plan view showing main parts of the semiconductor device A1. FIG. 3 is a bottom view showing main parts of the semiconductor device A1. FIG. 4 is a front view of the semiconductor device A1. FIG. 5 is a side view of the semiconductor device A1. FIG. 6 is a sectional view taken along line VI-VI in FIG. 3. FIG. 7 is a sectional view taken along line VII-VII in FIG. 3. FIG. 8 is an enlarged sectional view showing a main part of the semiconductor device A1. FIG. 9 is an enlarged bottom view showing a main part of the semiconductor device A1. FIG. 10 is an enlarged sectional view showing a main part of the semiconductor device A1. FIG. 11 is an enlarged bottom view showing a main part of the semiconductor device A1. In FIGS. 2 and 3, the sealing resin 8 is indicated by imaginary line for the convenience of understanding. In FIG. 3, a covered portion 7 is omitted for the convenience of understanding. FIG. 9 shows only a part of a second lead 2. FIG. 11 shows only a part of a third lead 3.

The first lead 1 supports the semiconductor element 4 and constitutes a conduction path to the semiconductor element 4. The material of the first lead 1 is not particularly limited. For example, the first lead may be made of a metal such as Cu, Ni, Fe, or an alloy of these. The first lead 1 may be formed with a plating layer made of a metal such as Ag, Ni, Pd or Au at appropriate portions. The thickness of the first lead 1 is not particularly limited and may be about 0.12 mm to 0.2 mm, for example.

The first lead 1 of the present embodiment includes a die pad portion 11 and two extensions 12.

The die pad portion 11 is a portion that supports the semiconductor element 4. The shape of the die pad portion 11 is not particularly limited and is rectangular as viewed in the z direction in the present embodiment. The die pad portion 11 has a die-pad obverse surface 111 and a die-pad reverse surface 112. The die-pad obverse surface 111 faces in the z direction. The die-pad reverse surface 112 faces away from the die-pad obverse surface 111 in a thickness direction. In the illustrated example, the die-pad obverse surface 111 and the die-pad reverse surface 112 are flat surfaces.

The two extensions 12 extend from the die pad portion 11 to opposite sides in the x direction. In the present embodiment, each extension 12 has a bent shape as a whole, including a portion extending from the die pad portion 11 along the x direction, a portion extending obliquely from the portion toward the die-pad obverse surface 111-side in the z direction, and a portion extending from the inclined portion along the x direction.

The second leads 2 are spaced apart from the first lead 1 and constitute a conduction path to the semiconductor element 4. In the present embodiment, the second leads 2 constitute the conduction path for the current switched by the semiconductor element 4. The second leads 2 are disposed on one side in the y direction with respect to the first lead 1. The second leads 2 are spaced apart from each other in the x direction.

The material of the second leads 2 is not particularly limited. For example, the second leads may be made of a metal such as Cu, Ni, Fe, or an alloy of these. The second leads 2 may be formed with a plating layer made of a metal such as Ag, Ni, Pd or Au at appropriate portions. The thickness of the second leads 2 is not particularly limited and may be about 0.12 mm to 0.2 mm, for example.

Each of the second leads 2 of the present embodiment has a bonding pad portion 21, a terminal portion 22, and a connecting portion 23.

The bonding pad portion 21 is a portion to which a first wire 51 is bonded. In the present embodiment, the bonding pad portion 21 is offset from the die pad portion 11 toward the side which the die-pad obverse surface 111 faces (i.e., the upper side in the figure) in the z direction.

The bonding pad portion 21 includes a bonding-pad obverse surface 211, a bonding-pad reverse surface 212, and a first portion 213. The bonding-pad obverse surface 211 is a surface that faces the same side as the die-pad obverse surface 111 in the z direction. Preferably, the entirety or a part of the bonding-pad obverse surface 211 is provided with the plating layer described above. The bonding-pad obverse surface 211 is offset from the die-pad obverse surface 111 toward the side which the die-pad obverse surface 111 faces (i.e., the upper side in the figure) in the z direction.

The bonding-pad reverse surface 212 is a surface that faces away from the bonding-pad obverse surface 211 in the z direction. The bonding-pad reverse surface 212 is offset from the die-pad reverse surface 112 toward the side which the die-pad obverse surface 111 faces (i.e., the upper side in the figure) in the z direction.

Each bonding pad portion 210 has a single first portion 213. The first portion 213 is connected to the bonding-pad reverse surface 212 and surrounded by the bonding-pad reverse surface 212 as viewed in the z direction. The first portion 213 includes a part present at a position different from the bonding-pad reverse surface 212 in the z direction. The specific configuration of the first portion 213 is not particularly limited. The first portion 213 of the present embodiment is a recess having an opening edge 2130 in the bonding-pad reverse surface 212 and recessed toward the bonding-pad obverse surface 211 in the z direction.

The specific configuration of the first portion 213 provided by a recess is not particularly limited. In the illustrated example, the first portion 213 has the opening edge 2130, a first surface 2131, and a bottom surface 2135. The opening edge 2130 is the edge adjoining the bonding-pad reverse surface 212. The shape of the opening edge 2130 is not particularly limited, and various shapes such as circular, elliptical, or polygonal shapes may be employed as appropriate. In the illustrated example, the opening edge 2130 is circular.

The first surface 2131 is inclined to become farther away from the bonding-pad reverse surface 212 as viewed in the z direction as proceeding farther away from the bonding-pad reverse surface 212 toward the bonding-pad obverse surface 211 in the z direction. The shape and size of the first surface 2131 are not particularly limited. In FIG. 8, the angle formed by the first surface 2131 and the x-y plane orthogonal to the z direction is indicated as an angle α1. Preferably, the angle α1 is equal to or greater than 25° and equal to or less than 50°, for example. In the illustrated example, the first surface 2131 has the shape of a ring, and more specifically, a circular ring as viewed in the z direction. With the first surface 2131 being such an inclined surface, the portions other than the opening edge 2130 of the first portion 213, which is a recess, are located inward from the opening edge 2130 as viewed in the z direction.

The bottom surface 2135 is a surface of the first portion 213 that is closest to the bonding-pad obverse surface 211 in the z direction. The specific shape and size of the bottom surface 2135 are not particularly limited, and various shapes such as circular, elliptical, or polygonal shapes may be employed as appropriate. In the illustrated example, the bottom surface 2135 is circular.

As one example of the size of the first portion 213, the depth of the first portion 213 in the z direction is equal to or greater than ¼ and equal to or less than ½ of the thickness of the bonding pad portion 21 (the second lead 2). As for the size of the first portion 213 as viewed in the z direction, the diameter of the opening edge 2130 is equal to or greater than 0.5 times and equal to or less than 5 times the thickness of the bonding pad portion 21 (the second lead 2) in the illustrated example.

The terminal portion 22 is a portion in the form of a strip extending outside the sealing resin 8 in the y direction. The terminal portion 22 is disposed at a position overlapping with the die pad portion 11 as viewed in the y direction.

The connecting portion 23 is a portion that connects the bonding pad portion 21 and the terminal portion 22 to each other. In the illustrated example, the connecting portion 23 has a bent shape as viewed in the x direction. The connecting portion 23 includes a portion covered with the sealing resin 8 and a portion exposed from the sealing resin 8.

The third leads 3 are spaced apart from the first lead 1 and constitute a conduction path to the semiconductor element 4. In the present embodiment, the third leads 3 constitute a conduction path for a control signal current for controlling the semiconductor element 4. The third leads 3 are disposed on the other side in the y direction with respect to the first lead 1. The third leads 3 are spaced apart from each other in the x direction.

The material of the third leads 3 is not particularly limited. For example, the third leads may be made of a metal such as Cu, Ni, Fe, or an alloy of these. The third lead 3 may be formed with a plating layer made of a metal such as Ag, Ni, Pd or Au at appropriate portions. The thickness of the third leads 3 is not particularly limited and may be about 0.12 mm to 0.2 mm, for example.

Each of the third leads 3 of the present embodiment has a bonding pad portion 31, a terminal portion 32, and a connecting portion 33.

The bonding pad portion 31 is a portion to which a second wire 52 is bonded. In the present embodiment, the bonding pad portion 31 is offset from the die pad portion 11 toward the side which the die-pad obverse surface 111 faces (i.e., the upper side in the figure) in the z direction.

The bonding pad portion 31 includes a bonding-pad obverse surface 311, a bonding-pad reverse surface 312, and a third portion 313. The bonding-pad obverse surface 311 is a surface that faces the same side as the die-pad obverse surface 111 in the z direction. Preferably, the entirety or a part of the bonding-pad obverse surface 311 is provided with the plating layer described above. The bonding-pad obverse surface 311 is offset from the die-pad obverse surface 111 toward the side which the die-pad obverse surface 111 faces (i.e., the upper side in the figure) in the z direction.

The bonding-pad reverse surface 312 is a surface that faces away from the bonding-pad obverse surface 311 in the z direction. The bonding-pad reverse surface 312 is offset from the die-pad reverse surface 112 toward the side which the die-pad obverse surface 111 faces (i.e., the upper side in the figure) in the z direction.

Each bonding pad portion 310 has a single third portion 313. The third portion 313 is connected to the bonding-pad reverse surface 312 and surrounded by the bonding-pad reverse surface 312 as viewed in the z direction. The third portion 313 includes a part present at a position different from the bonding-pad reverse surface 312 in the z direction. The specific configuration of the third portion 313 is not particularly limited. The third portion 313 of the present embodiment is a recess having an opening edge 3130 in the bonding-pad reverse surface 312 and recessed toward the bonding-pad obverse surface 311 in the z direction.

The specific configuration of the third portion 313 provided by a recess is not particularly limited. In the illustrated example, the third portion 313 has the opening edge 3130, a first surface 3131, and a bottom surface 3135. The opening edge 3130 is the edge adjoining the bonding-pad reverse surface 312. The shape of the opening edge 3130 is not particularly limited, and various shapes such as circular, elliptical, or polygonal shapes may be employed as appropriate. In the illustrated example, the opening edge 3130 is circular.

The first surface 3131 is inclined to become farther away from the bonding-pad reverse surface 312 as viewed in the z direction as proceeding farther away from the bonding-pad reverse surface 312 toward the bonding-pad obverse surface 311 in the z direction. The shape and size of the first surface 3131 are not particularly limited. In FIG. 10, the angle formed by the first surface 3131 and the x-y plane orthogonal to the z direction is indicated as an angle α2. Preferably, the angle α2 is equal to or greater than 25° and equal to or less than 50°, for example. In the illustrated example, the first surface 3131 has the shape of a ring, and more specifically, a circular ring as viewed in the z direction. With the first surface 3131 being such an inclined surface, the portions other than the opening edge 3130 of the third portion 313, which is a recess, are located inward from the opening edge 3130 as viewed in the z direction.

The bottom surface 3135 is a surface of the third portion 313 that is closest to the bonding-pad obverse surface 311 in the z direction. The specific shape and size of the bottom surface 3135 are not particularly limited, and various shapes such as circular, elliptical, or polygonal shapes may be employed as appropriate. In the illustrated example, the bottom surface 3135 is circular.

As one example of the size of the third portion 313, the depth of the third portion 313 in the z direction is equal to or greater than ¼ and equal to or less than ½ of the thickness of the bonding pad portion 31 (the third lead 3). As for the size of the third portion 313 as viewed in the z direction, the diameter of the opening edge 3130 is equal to or greater than 0.5 times and equal to or less than 5 times the thickness of the bonding pad portion 31 (the third lead 3) in the illustrated example.

The terminal portion 32 is a portion in the form of a strip extending outside the sealing resin 8 in the y direction. The terminal portion 32 is disposed at a position overlapping with the die pad portion 11 as viewed in the y direction.

The connecting portion 33 is a portion that connects the bonding pad portion 31 and the terminal portion 32 to each other. In the illustrated example, the connecting portion 33 has a bent shape as viewed in the x direction. The connecting portion 33 includes a portion covered with the sealing resin 8 and a portion exposed from the sealing resin 8.

The semiconductor element 4 is an element that performs electrical functions of the semiconductor device A1. The specific configuration of the semiconductor element 4 is not particularly limited, and various types of semiconductor elements can be selected as appropriate. In the present embodiment, the semiconductor element 4 performs a switching function. The semiconductor element 4 has an element body 40, a first electrode 401, a second electrode 402, and a plurality of third electrodes 403. The semiconductor element 4 also has a control section 48. Thus, the semiconductor element 4 has a part that constitutes a transistor for performing a switching function and a part that controls, monitors or protects the transistor.

The specific configuration of the semiconductor element 4 is not particularly limited. For example, the semiconductor element 4 may have e.g., a functional layer 408 as a part that constitutes a transistor and may not include the control section 48. In this case, the number and presence/absence of the second electrode 402 and the third electrodes 403 are selected as appropriate. In addition to the semiconductor element 4, other semiconductor elements may also be mounted to the die pad portion 11. The function of the semiconductor elements other than the semiconductor element 4 is not particularly limited.

The element body 40 has an element obverse surface 40a and an element reverse surface 40b. The element obverse surface 40a is a surface that faces the same side as the die-pad obverse surface 111 in the z direction. The element reverse surface 40b is a surface that faces away from the element obverse surface 40a in the z direction. The material of the element body 40 is not particularly limited. Examples of the material of the element body 40 include semiconductor materials such as Si, SiC and GaN, for example.

The element body 40 may have a functional layer 408. A transistor structure, such as a MOSFET (Metal Oxide Semiconductor Field Effect Transistor) or a MISFET (Metal Insulator Semiconductor Field Effect Transistor), is formed in the functional layer 408. As viewed in the z direction, the functional layer 408 is disposed side by side with the control section 48 in the y direction. The specific arrangement or the like of the functional layer 408 and the control section 48 is not particularly limited.

The first electrode 401 is disposed on the element obverse surface 40a of the element body 40. The shape, size and position of the first electrode 401 are not particularly limited. In the illustrated example, the first electrode 401 is disposed on a portion of the element obverse surface 40a that is closer to the second leads 2 in the y direction. The first electrode 401 overlaps with the functional layer 408 as viewed in the z direction. In the present embodiment, the first electrode 401 is spaced apart from the control section 48 as viewed in the z direction. In the present embodiment, the first electrode 401 is a source electrode. The material of the first electrode 401 is not particularly limited, and examples of the material include metals such as Al (aluminum), Al—Si, Cu (copper), and alloys containing these. The first electrode 401 may be a laminate of a plurality of layers made of different materials selected from these metals.

The second electrode 402 is disposed on the element reverse surface 40b of the element body 40. The second electrode 402 overlaps with the functional layer 408 and the control section 48 as viewed in the z direction and covers the entirety of the element reverse surface 40b in the present embodiment. In the present embodiment, the second electrode 402 is a drain electrode. The material of the second electrode 402 is not particularly limited, and examples of the material include metals such as Al, Al—Si, Cu, and alloys containing these. The second electrode 402 may be a laminate of a plurality of layers made of different materials selected from these metals.

The specific configuration of the control section 48 is not particularly limited. The control section 48 includes, for example, a current sensor circuit, a temperature sensor circuit, an overcurrent protection circuit, a heating protection circuit, an undervoltage lock out circuit, and the like.

The third electrodes 403 are disposed on the element obverse surface 40a. In the illustrated example, the third electrodes 403 are disposed on a portion of the element obverse surface 40a that is closer to the third leads 3 in the y direction. The third electrodes 403 overlap with the control section 48 as viewed in the z direction. In the present embodiment, the third electrodes 403 mainly electrically conduct to the control section 48. The number of third electrodes 403 is not particularly limited. Only a single third electrode 403 may be provided. In the illustrated example, the semiconductor element 4 has four third electrodes 403.

The first wires 51 electrically connect the first electrode 401 of the semiconductor element 4 and the second leads 2 to each other. The material of the first wires 51 is not particularly limited. For example, the first wires may be made of a metal such as Au, Cu or Al. As shown in FIGS. 2, 7 and 8, each of the first wires 51 of the present embodiment has a bonding portion 511, a bonding portion 512, and a loop portion 513. The specific configuration of the first wires 51 is not particularly limited. In the illustrated example, the first wires 51 are made of a material containing Cu and formed with a capillary, for example. In the present embodiment, the current switched by the semiconductor element 4 flows through the first wires 51.

The bonding portions 511 are bonded to the first electrode 401 of the semiconductor element 4 and disposed at positions overlapping with the first electrode 401 as viewed in the z direction. In the present embodiment, the bonding portions 511 are so-called first bonding portions.

The arrangement of the bonding portions 511 is not particularly limited. In the illustrated example, the bonding portions 511 of the first wires 51 are distributed over the substantially entire area of the first electrode 401. The bonding portions 511 of the first wires 51 may be arranged in one or a plurality of rows along the peripheral edge of the first electrode 401, for example.

The bonding portions 512 are bonded to the bonding-pad obverse surfaces 211 of the bonding pad portions 21 of the second leads 2. The bonding portions 512 are so-called second bonding portions. In the illustrated example, a plurality of bonding portions 512 are disposed on each of the bonding pad portions 21. Preferably, at least a part of one of the bonding portions 512 bonded to a bonding pad portion 21 overlaps with at least a part of the relevant first portion 213 as viewed in the z direction. However, the bonding portions 512 bonded to a bonding pad portion 21 and the relevant first portion 213 may not overlap with each other as viewed in the z direction.

In the present embodiment, the loop portions 513 are connected to the bonding portions 511 and the bonding portions 512 and have a curved shape.

The second wires 52 electrically connect the third electrodes 403 of the semiconductor element 4 and the third leads 3 to each other. The material of the second wires 52 is not particularly limited. For example, the second wires may be made of a metal such as Au, Cu or Al. Each of the second wires 52 has a bonding portion 521, a bonding portion 522, and a loop portion 523. The specific configuration of the second wires 52 is not particularly limited. In the illustrated example, the second wires 52 are formed with a capillary, for example. In the present embodiment, the control signal current for controlling the semiconductor element 4 flows through the second wires 52.

The bonding portions 521 are bonded to the second electrodes 402 of the semiconductor element 4. The bonding portions 521 are so-called first bonding portions.

The bonding portions 522 are bonded to the bonding-pad obverse surfaces 311 of the bonding pad portions 31 of the third leads 3. The bonding portions 522 are so-called second bonding portions. In the illustrated example, one bonding portion 522 is disposed on each of the bonding pad portions 31. Preferably, at least a part of the bonding portion 522 overlaps with at least a part of the third portion 313 as viewed in the z direction. Alternatively, the bonding portion 522 and the third portion 313 may not overlap with each other as viewed in the z direction.

The loop portions 523 are connected to the bonding portions 521 and the bonding portions 522 and have a curved shape.

The sealing resin 8 covers the first lead 1, the second leads 2, the third leads 3, the semiconductor element 4, the first wires 51, the second wires 52, and a covered portion 7. In the illustrated example, a part of the first lead 1, a part of each second lead 2, and a part of each third lead 3 are exposed from the sealing resin 8. The sealing resin 8 is made of an insulating resin such as an epoxy resin mixed with a filler. In the present embodiment, portions of the sealing resin 8 fill the first portions 213 of the second leads 2 and the third portions 313 of the third leads 3.

The shape of the sealing resin 8 is not particularly limited. In the illustrated example, the sealing resin 8 includes a resin obverse surface 81, a resin reverse surface 82, two first resin side surfaces 83, and two second resin side surfaces 84.

The resin obverse surface 81 faces the same side as the die-pad obverse surface 111 in the z direction and is a flat surface, for example. The resin reverse surface 82 faces away from the resin obverse surface 81 in the z direction and is a flat surface, for example.

The two first resin side surfaces 83 are located between the resin obverse surface 81 and the resin reverse surface 82 in the z direction and face away from each other in the x direction. The two second resin side surfaces 84 are located between the resin obverse surface 81 and the resin reverse surface 82 in the z direction and face away from each other in the y direction.

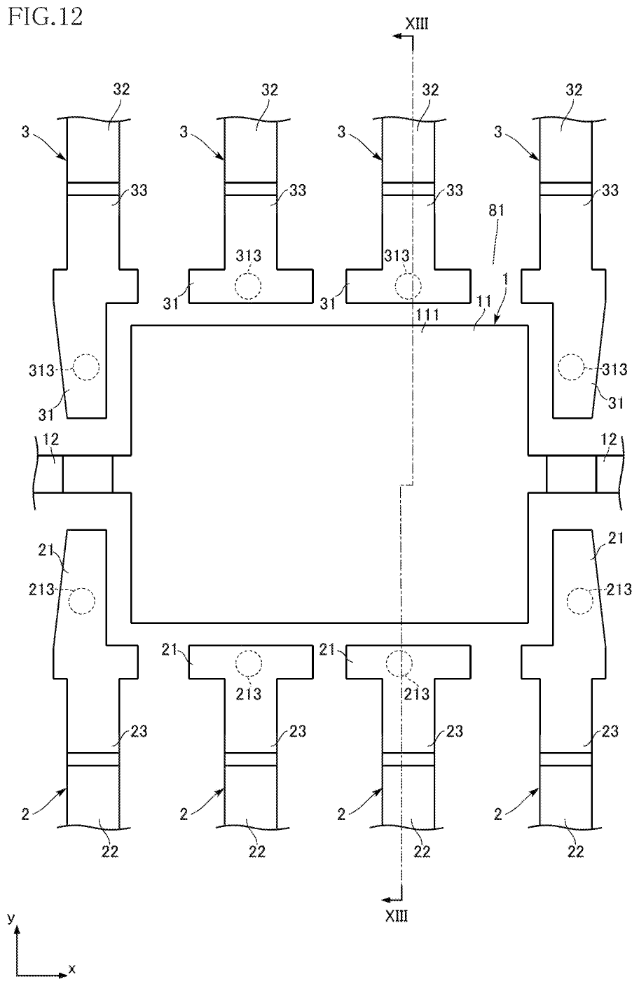

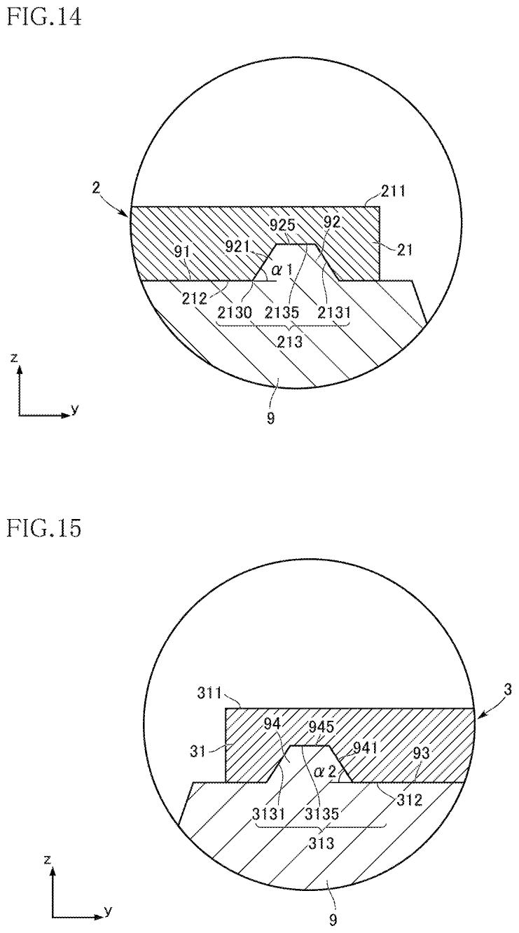

An example of a method for manufacturing the semiconductor device A1 is described below with reference to FIGS. 12 to 22.

First, as shown in FIGS. 12 to 15, the first lead 1, the plurality of second leads 2, and the plurality of third leads 3 are prepared. As the first lead 1, the second leads 2 and the third leads 3, use may be made of separated pieces or a lead frame including a frame portion (not shown) connecting these together. When a lead frame is used, the first lead 1, the second leads 2, and the third leads 3 as separated pieces are obtained by cutting the lead frame at appropriate locations after the steps described below are completed.

The first lead 1, the second leads 2 and the third leads 3 are supported by a support 9. The support 9 is a member made of a metal, for example. The specific configuration of the support 9 is not particularly limited. In the present embodiment, the support 9 has a base surface 90, a support surface 91, second portions 92, a support surface 93, and fourth portions 94.

The base surface 90 is a surface that occupies most of the area of the support 9 and faces the upper side in the figure (i.e., the side which the die-pad obverse surface 111 faces) in the z direction. The base surface 90 supports the die pad portion 11, the terminal portions 22, the terminal portions 32, and the like.

The support surface 91 faces the upper side in the figure (i.e., the side which the die-pad obverse surface 111 faces) in the z direction and is located on the upper side in the figure (i.e., the side which the die-pad obverse surface 111 faces) relative to the base surface 90. The support surface 91 supports the bonding pad portions 21 and is held in contact with the bonding-pad reverse surfaces 212.

The second portions 92 are portions that engage with the first portions 213 of the bonding pad portions 21 of the second leads 2. The specific configuration of the second portions 92 is not particularly limited. In the illustrated example, the second portions 92 are protrusions having the shape of a truncated cone that conforms to the configuration of the first portions 213 described above. Each of the second portions 92 has a first surface 921 and a top surface 925.

The first surface 921 is a surface that faces and may be held in contact with the first surface 2131. The first surface 921 is inclined by an angle α1 (or 180°−angle α1) with respect to the x-y plane, as with the first surface 2131. The first surface 921 has the shape of a circular ring as viewed in the z direction, as with the first surface 2131.

The top surface 925 is the end surface of the second portion 92, which is a protrusion. The top surface 925 faces and may be held in contact with the bottom surface 2135. The top surface 925 is circular correspondingly to the bottom surface 2135.

The support surface 93 faces the upper side in the figure (i.e., the side which the die-pad obverse surface 111 faces) in the z direction and is located on the upper side in the figure (i.e., the side which the die-pad obverse surface 111 faces) relative to the base surface 90. The support surface 93 supports the bonding pad portions 31 and is held in contact with the bonding-pad reverse surfaces 312.

The fourth portions 94 are portions that engage with the third portions 313 of the bonding pad portions 31 of the third leads 3. The specific configuration of the fourth portions 94 is not particularly limited. In the illustrated example, the fourth portions 94 are protrusions having the shape of a truncated cone that conforms to the configuration of the third portions 313 described above. Each of the fourth portions 94 has a first surface 941 and a top surface 945.

The first surface 941 is a surface that faces and may be held in contact with the first surface 3131. The first surface 941 is inclined by an angle α2 (or 180°−angle α2) with respect to the x-y plane, as with the first surface 3131. The first surface 941 has the shape of a circular ring (i.e., annular shape) as viewed in the z direction, as with the first surface 3131.

The top surface 945 is the end surface of the fourth portion 94, which is a protrusion. The top surface 945 faces and may be held in contact with the bottom surface 3135. The top surface 945 is circular correspondingly to the bottom surface 3135.

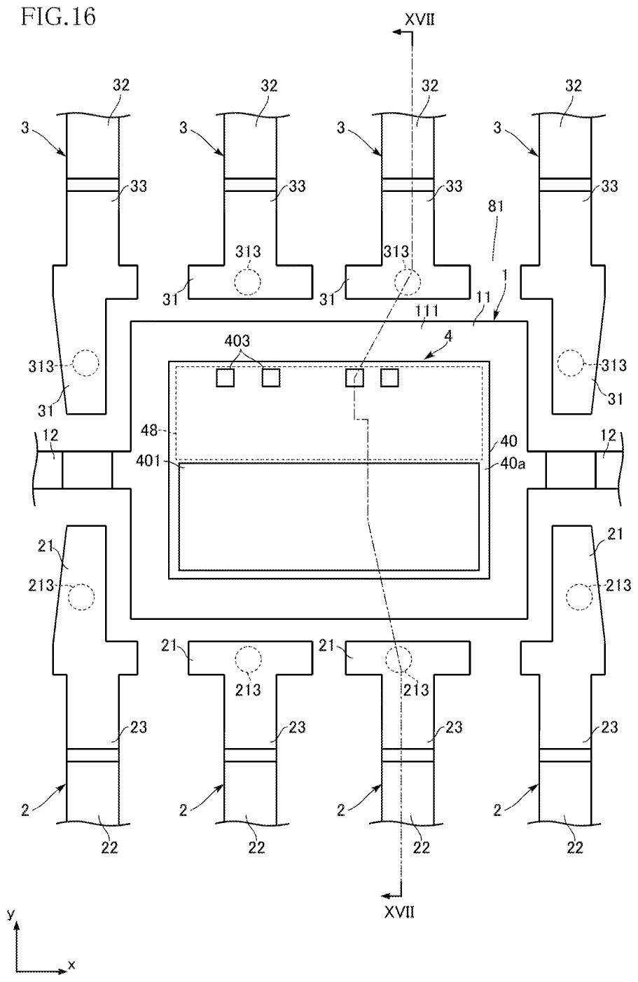

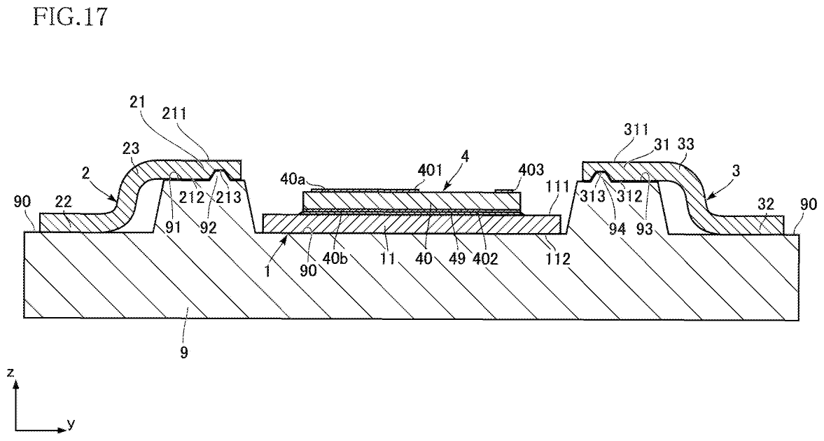

Next, as shown in FIGS. 16 and 17, the semiconductor element 4 is mounted on the first lead 1. Specifically, the second electrode 402 of the semiconductor element 4 and the die-pad obverse surface 111 of the die pad portion 11 of the first lead 1 are bonded together with a bonding paste, which will become a bonding material 49.

Next, bonding of first wires 51 and second wires 52 are performed. The order of bonding the first wires 51 and the second wires 52 is not particularly limited. The second wires 52 may be bonded after all of the first wires 51 are bonded, or the first wires 51 may be bonded after all of the second wires 52 are bonded. As another example, the first wires 51 and the second wires 52 may be alternately bonded. In the description below, bonding of a first wire 51 is first explained. Bonding of a second wire 52 is performed by a method similar to that for bonding a first wire 51.

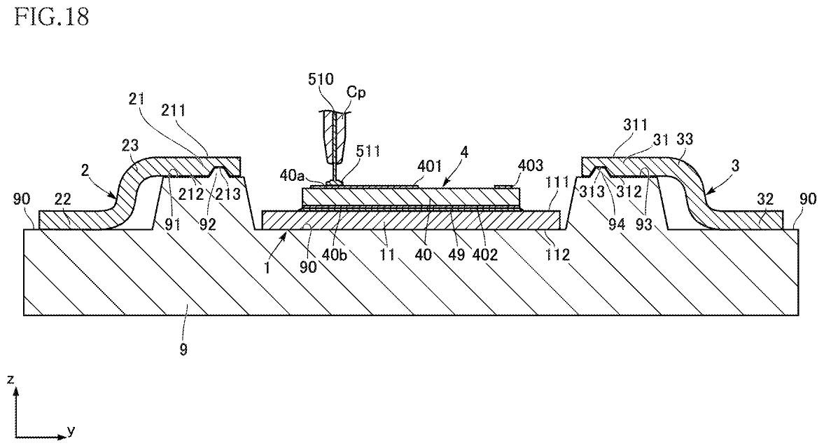

First, as shown in FIG. 18, first bonding is performed on the first electrode 401 using a capillary Cp. The capillary Cp holds a wire material 510 so as to allow advancing/retracting movement of the wire material. A predetermined amount of wire material 510 is dispensed from the capillary Cp and melted. The wire material 510 in such a melted state is applied to the first electrode 401. Thus, the bonding portion 511 is formed.

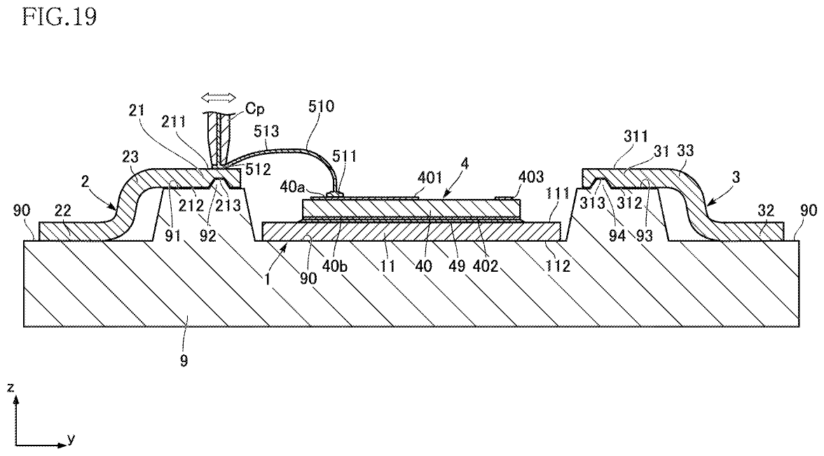

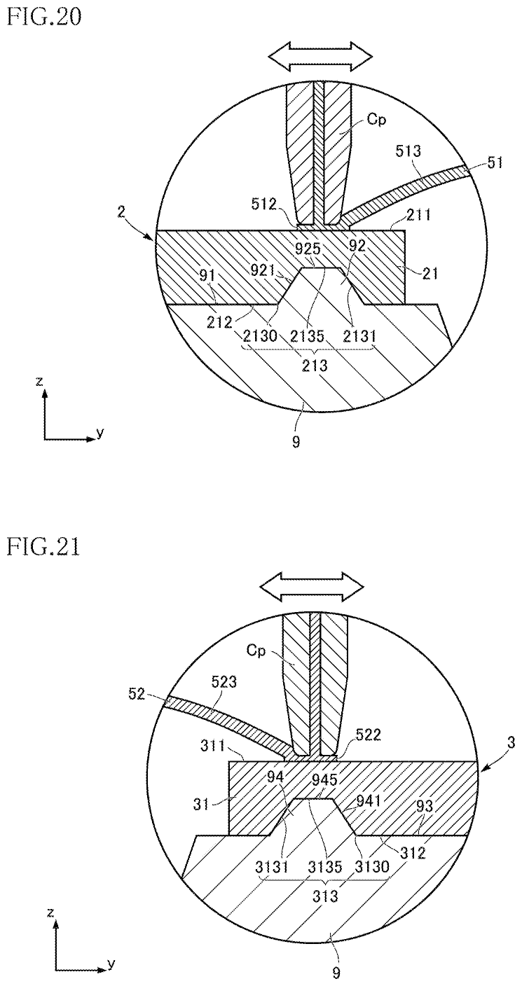

Next, while feeding the wire material 510 from the capillary Cp, the capillary Cp is moved closer to the bonding pad portion 21 of the second lead 2 along a predetermined path. Thus, the loop portion 513 shown in FIG. 19 is formed. Next, the wire material 510 is pressed against the bonding-pad obverse surface 211 of the bonding pad portion 21 by the capillary Cp. Preferably, in this process, the wire material 510 is pressed against a position overlapping with the first portion 213 as viewed in the z direction. However, the wire material 510 may be pressed against a position that does not overlap with the first portion 213. Next, as shown in FIG. 20, force and vibration are applied to the wire material 510 by the capillary Cp. The vibration may be ultrasonic vibration, for example. Thus, the wire material 510 is bonded to the bonding-pad obverse surface 211. Next, the capillary Cp is separated from the bonding pad portion 21 upward in the z direction without feeding the wire material 510. In this way, the first wire 51 having the bonding portion 511, the bonding portion 512 and the loop portion 513 is formed.

Formation of a second wire 52 is performed using the capillary Cp, as with the formation of a first wire 51. For example, as shown in FIG. 21, after the bonding portion 521 and the loop portion 523 are formed, the bonding portion 522 is formed on the bonding-pad obverse surface 311 of the bonding pad portion 31 of a third lead 3. As with the formation of the bonding portion 512, the formation of the bonding portion 522 is performed by pressing the wire material 510 against the bonding-pad obverse surface 311 of the bonding pad portion 31 with the capillary Cp. Preferably, in this process, the wire material 530 is pressed against a position overlapping with the third portion 313 as viewed in the z direction. However, the wire material 510 may be pressed against a position that does not overlap with the third portion 313.

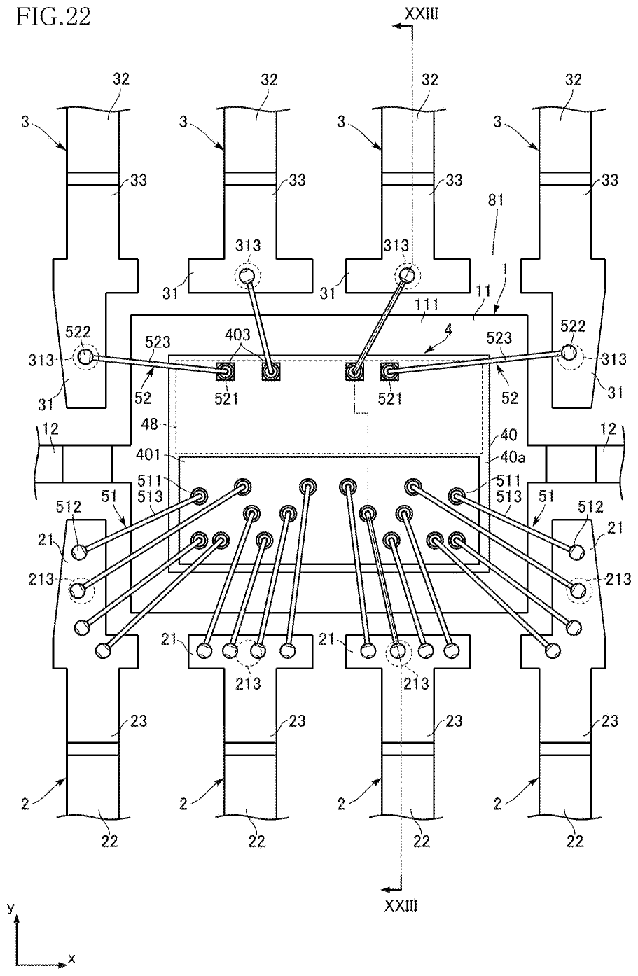

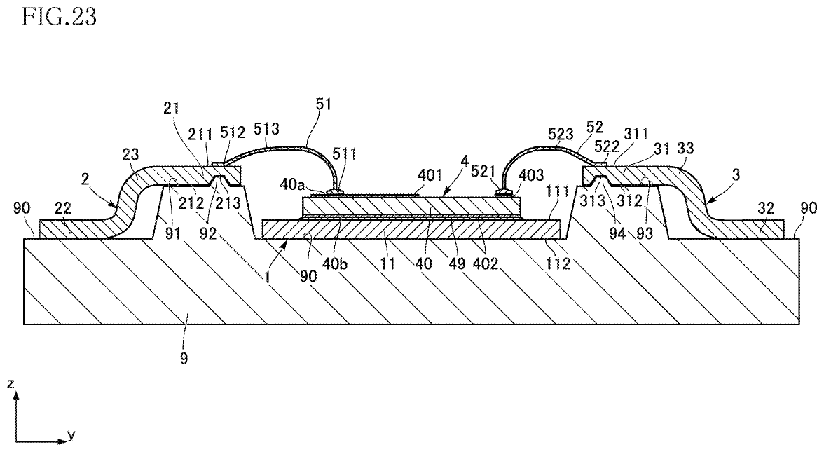

The bonding process for a first wire 51 and a second wire 52 are repetitively performed to form the plurality of first wires 51 and the plurality of second wires 52, as shown in FIGS. 22 and 23. Thereafter, the first lead 1, the second leads 2, the third leads 3, the semiconductor element 4, the first wires 51, and the second wires 52 are separated from the support 9. Next, the sealing resin 8 is formed by molding, for example. Thus, the semiconductor device A1 described above is obtained.

The advantages of the semiconductor device A1 and the method for manufacturing the semiconductor device A1 are described below.

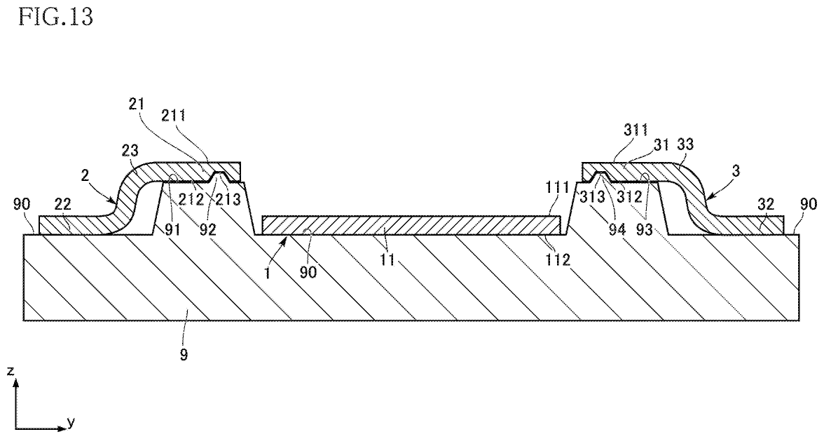

According to the present embodiment, the bonding pad portion 21 has the first portion 213. During the manufacturing process of the semiconductor device A1, the first portion 213 engages with the second portion 92 of the support 9, as shown in FIGS. 13 and 14. With such a configuration, when force and vibration is applied by e.g., the capillary Cp during the bonding of the first wire 51, accidental displacement of the bonding pad portion 21 along the x-y plane is prevented, as shown in FIGS. 19 and 20. According to the present embodiment, therefore, the first wires 51 can be bonded more reliably.

The first portion 213 overlaps with the bonding portion 512 as viewed in the z direction. With such a configuration, the force and vibration applied during the formation of the bonding portion 512 is reliably received by the engagement structure between the bonding portion 512 and the second portion 92.

Since the bonding portion 512 is the second bonding portion, a larger force and vibration tend to be applied to the bonding pad portion 21 during the formation of the bonding portion 512. Adopting the engagement structure between the first portion 213 and the second portion 92 allows proper formation of the bonding portion 512, which is the second bonding portion.

The first portion 213 is provided by a recess. Thus, the first portion 213 does not interfere with other members or the like during the manufacturing process of the semiconductor device A1.

The first surface 2131 of the first portion 213 is inclined to become farther away from the bonding-pad reverse surface 212 as viewed in the z direction as proceeding farther away from the bonding-pad reverse surface 212 in the z direction. As will be understood from FIG. 20, such a configuration allows the second portion 92 to engage with the first portion 213 and also allows smooth removal of the bonding pad portion 21 from the support 9 after the completion of bonding of the first wire 51. When the second lead 2 is placed on the support 9, the first portion 213 may be in a position slightly misaligned with respect to the second portion 92. Even in such a case, when the bonding pad portion 21 is pressed downward in the z direction, the second portion 92 and the first portion 213 engage with each other, so that the bonding pad portion 21 is guided to a proper position with respect to the support 9 (the second portion 92). To more reliably achieve the effect of the first surface 2131 being an inclined surface, it is preferable that the angle α1 is equal to or greater than 25° and equal to or less than 50°.

The depth of the first portion 213 in the z direction being equal to or greater than ¼ and equal to or less than ½ of the thickness of the second lead 2 (the bonding pad portion 21) is desirable for preventing reduction in rigidity of the bonding pad portion 21 while realizing proper engagement between the first portion 213 and the second portion 92.

The effect of the engagement structure between the first portion 213 and the second portion 92 and each part of these is similarly achieved by the engagement structure between the third portion 313 and the fourth portion 94 and each part of these.

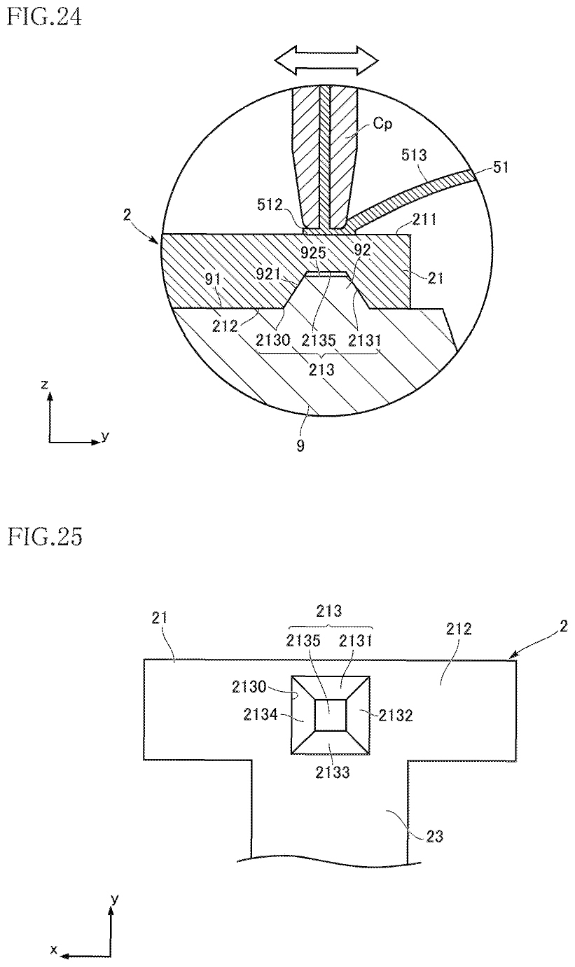

FIGS. 24 to 33 show variations and other embodiments of the present disclosure. In these figures, the elements that are identical or similar to those of the foregoing embodiment are denoted by the same reference signs as those used for the foregoing embodiment.

FIG. 24 shows a first variation of the method for manufacturing the semiconductor device A1. In this variation, the first surface 2131 of the first portion 213 of the bonding pad portion 21 and the first surface 921 of the second portion 92 are held in contact with each other, while the bottom surface 2135 of the first portion 213 and the top surface 925 of the second portion 92 are spaced apart from each other. That is, in this variation, the height of the second portion 92 in the z direction is smaller than the depth of the first portion 213 in the z direction.

According to the present variation again, the first wires 51 can be bonded more reliably. As will be understood from this variation, the specific configuration of the first portion 213 and the second portion 92 and the contact/non-contact state of the parts of the first portion 213 and the second portion 92 are not particularly limited. Note that the configurations of the first portion 213 and the second portion 92 explained in the present and following variations or embodiments are also applicable to the third portion 313 and the fourth portion 94.

Since the height of the second portion 92 is smaller than the depth of the first portion 213, the bonding-pad reverse surface 212 and the support surface 91 can be reliably brought into contact with each other. Moreover, when the size of the opening edge 2130 is made smaller than the size of the boundary between the second portion 92 and the support surface 91, the first surface 2131 and the first surface 921 can be brought into contact with each other more reliably. This prevents displacement of the bonding pad portion 21 within the x-y plane during the bonding of the first wire 51 using the capillary Cp.

FIG. 25 shows a first portion 213 according to a second variation of the semiconductor device A1. The first portion 213 of the present variation has an opening edge 2130, a first surface 2131, a second surface 2132, a third surface 2133, a fourth surface 2134, and a bottom surface 2135.

The opening edge 2130 is rectangular as viewed in the z direction. As with the first surface 2131 described above, each of the first surface 2131, the second surface 2132, the third surface 2133 and the fourth surface 2134 may be inclined by an angle α1 with respect to the x-y plane. The first surface 2131, the second surface 2132, the third surface 2133 and the fourth surface 2134 are at positions different from each other as viewed in the z direction. In the present variation, the first surface 2131, the second surface 2132, the third surface 2133 and the fourth surface 2134 are disposed to form a rectangular ring surrounding the bottom surface 2135 as viewed in the z direction.

According to the present variation again, the first wires 51 can be bonded more reliably. As will be understood from the present variation, the specific configuration of the first portion 213 is not particularly limited. The shape and size of the second portion 92 may be selected appropriately according to the shape and size of the first portion 213 so as to be engageable with the first portion.

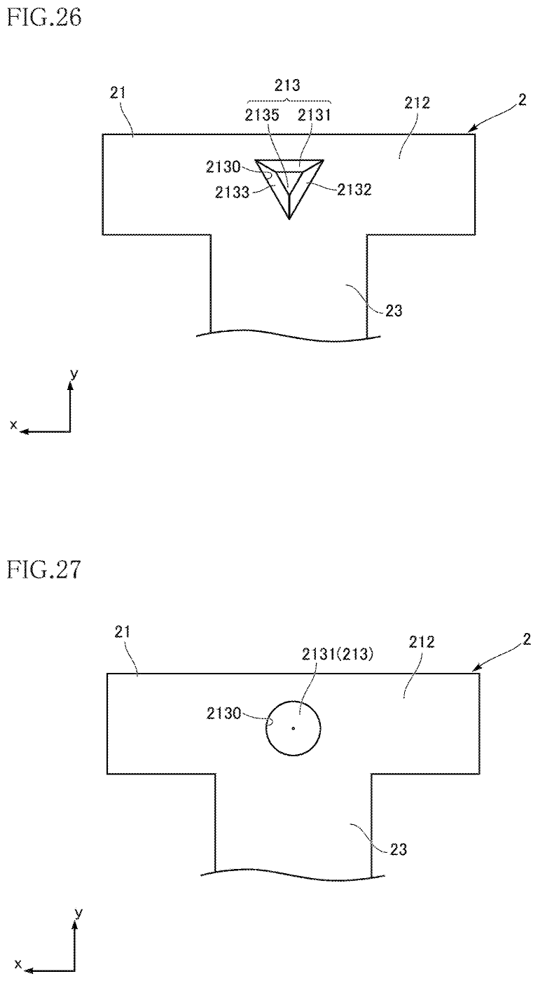

FIG. 26 shows a first portion 213 according to a third variation of the semiconductor device A1. The first portion 213 of the present variation has an opening edge 2130, a first surface 2131, a second surface 2132, a third surface 2133 and a bottom surface 2135.

The opening edge 2130 is triangular as viewed in the z direction. As with the first surface 2131 described above, each of the first surface 2131, the second surface 2132 and the third surface 2133 may be inclined by an angle α1 with respect to the x-y plane. The first surface 2131, the second surface 2132 and the third surface 2133 are at positions different from each other as viewed in the z direction. In the present variation, the first surface 2131, the second surface 2132 and the third surface 2133 are disposed to form a triangular ring surrounding the bottom surface 2135 as viewed in the z direction.

According to the present variation again, the first wires 51 can be bonded more reliably. As will be understood from the present variation, the specific configuration of the first portion 213 is not particularly limited. The opening edge 2130 of the first portion 213 may be polygonal.

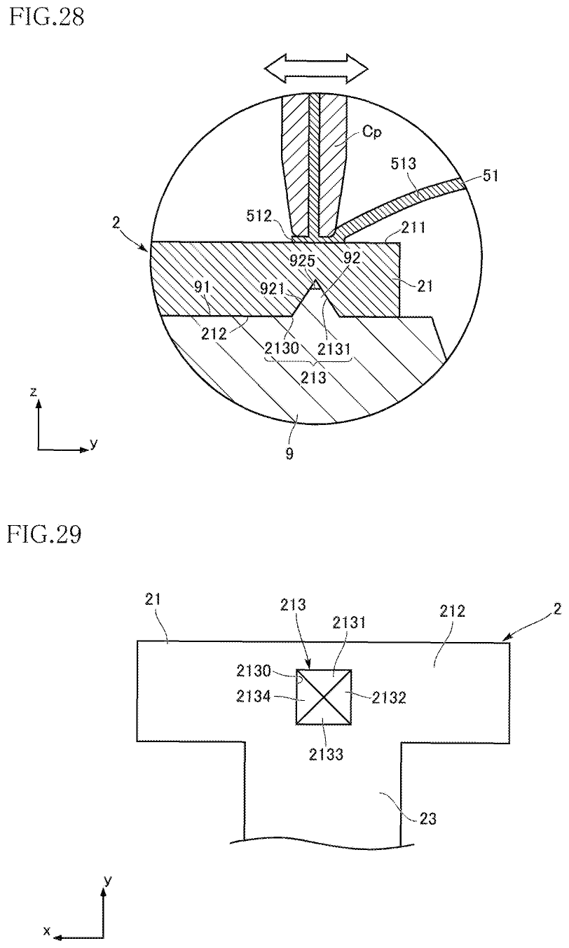

FIGS. 27 and 28 shows a first portion 213 according to a fourth variation of the semiconductor device A1. The first portion 213 of the present variation has an opening edge 2130 and a first surface 2131 and does not have the bottom surface 2135 described above.

The first surface 2131 of the present variation forms a conical shape. When a first wire 51 is bonded to a bonding pad portion 21 having such a first portion 213, the second portion 92 having the shape of a truncated cone as shown in FIG. 28 may be employed.

According to the present variation again, the first wires 51 can be bonded more reliably. As will be understood from the present variation, the first portion 213 may not have the bottom surface 2135.

FIG. 29 shows a first portion 213 according to a fifth variation of the semiconductor device A1. The first portion 213 of the present variation has a first surface 2131, a second surface 2132, a third surface 2133 and a fourth surface 2134 and does not have the bottom surface 2135, as with the fourth variation. The first portion 213 has a pyramidal shape. According to the present variation again, the first wires 51 can be bonded more reliably.

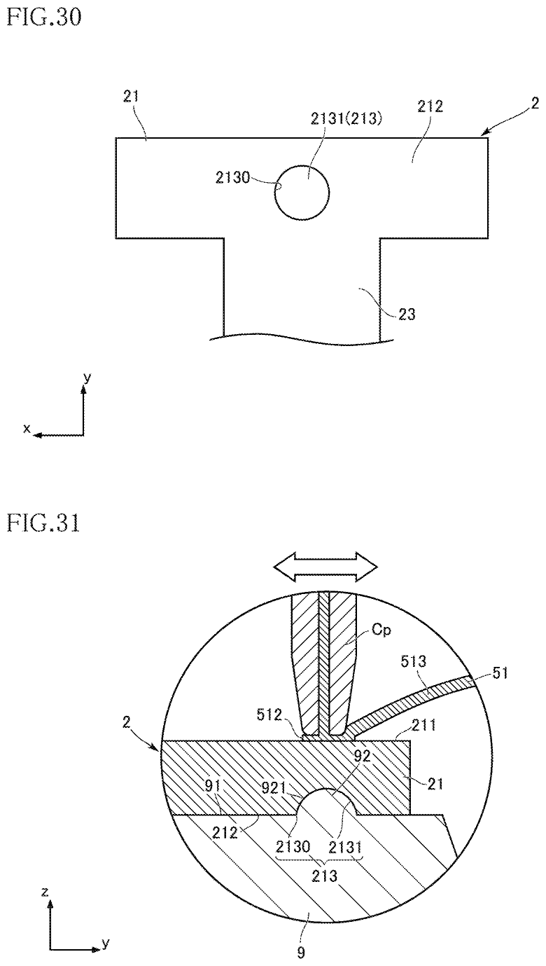

FIGS. 30 and 31 show a first portion 213 according to a sixth variation of the semiconductor device A1. The first portion 213 of the present variation has an opening edge 2130 and a first surface 2131. The first surface 2131 is entirely concave. The first portion 213 has a hemispherical shape (or a substantially hemispherical shape) as a whole. Preferably, the angle α1 of the portion of the first surface 2131 that is connected to the opening edge 2130 is sufficiently smaller than 90°.

In the present variation, the second portion 92 having a hemispherical shape (or a substantially hemispherical shape) as shown in FIG. 31 may be employed. As another example, the second portion 92 may have a substantially hemispherical shape with a flat top surface 925 (see FIG. 14).

According to the present variation again, the first wires 51 can be bonded more reliably. As will be understood from the present variation, the first surface 2131 may be a concavely curved surface or a convexly curved surface.

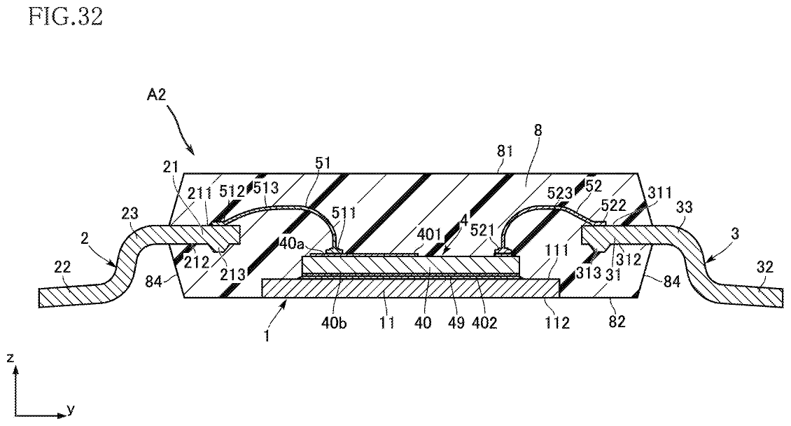

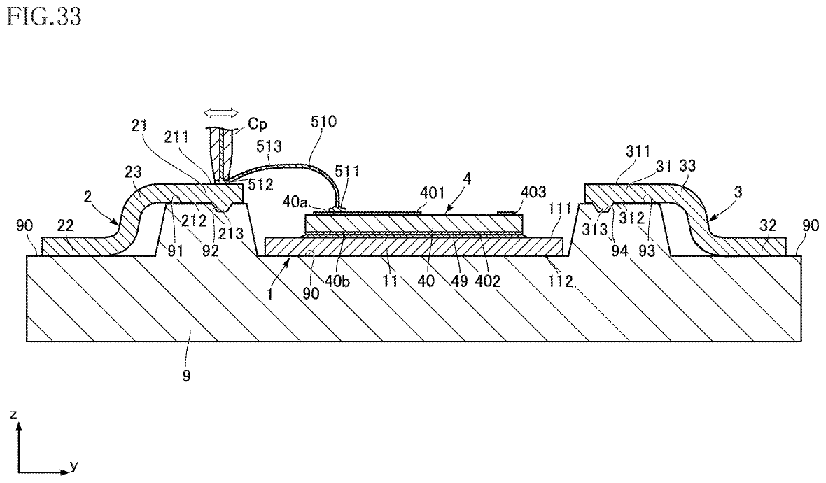

FIGS. 32 and 33 show a semiconductor device and a method for manufacturing a semiconductor device according to a second embodiment of the present disclosure. The semiconductor device A2 according to the present embodiment differs from the semiconductor device A1 in configurations of the first portion 213 and the third portion 313.

In the present embodiment, the first portion 213 is provided by a protrusion that protrudes from the bonding-pad reverse surface 212 toward the side which the bonding-pad reverse surface 212 faces in the z direction. In the present embodiment again, each bonding pad portion 21 has a single first portion 213. The first portion 213 is connected to the bonding-pad reverse surface 212 and surrounded by the bonding-pad reverse surface 212 as viewed in the z direction. The first portion 213 of the present embodiment also includes a part present at a position different from the bonding-pad reverse surface 212 in the z direction.

The third portion 313 is provided by a protrusion that protrudes from the bonding-pad reverse surface 312 toward the side which the bonding-pad reverse surface 312 faces in the z direction. In the present embodiment again, each bonding pad portion 31 has a single third portion 313. The third portion 313 is connected to the bonding-pad reverse surface 312 and surrounded by the bonding-pad reverse surface 312 as viewed in the z direction. The third portion 313 of the present embodiment also includes a part present at a position different from the bonding-pad reverse surface 312 in the z direction.

A method for manufacturing the semiconductor device A2 uses a support 9 in which a second portion 92 and a fourth portion 94 are provided by recesses engageable with the first portion 213 and the third portion 313, respectively. By using the support 9 having such a configuration, bonding of the first wires 51 and the second wires 52 can be performed, with the first portion 213 and the third portion 313 reliably held in engagement with the second portion 92 and the fourth portion 94, respectively.

According to the present embodiment again, the first wires 51 can be bonded more reliably. As will be understood from the present embodiment, the first portion 213 and the third portion 313 may be provided by a recess or may be provided by a protrusion.

A semiconductor device and a method for manufacturing a semiconductor device according to the present disclosure are not limited to the foregoing embodiments. The specific configuration of a semiconductor device and a method for manufacturing a semiconductor device according to the present disclosure can be changed in design in many ways. The present disclosure includes the embodiments described in the following clauses.

Clause 1.

A semiconductor device comprising:
a semiconductor element including an element body containing a semiconductor and a first electrode disposed on the element body;
a first lead on which the semiconductor element is mounted;
a second lead; and
a first wire electrically connecting the semiconductor element and the second lead, wherein
the first lead includes a die pad portion including a die-pad obverse surface and a die-pad reverse surface facing away from each other in a thickness direction,
the semiconductor element is mounted on the die-pad obverse surface,
the second lead includes a bonding pad portion including a bonding-pad obverse surface facing a same side as the die-pad obverse surface in the thickness direction and a bonding-pad reverse surface facing away from the bonding-pad obverse surface,
the bonding-pad reverse surface is offset from the die-pad reverse surface toward the die-pad obverse surface-side in the thickness direction,
the first wire is bonded to the first electrode and the bonding-pad obverse surface, and
the bonding pad portion includes a single first portion, the first portion being connected to the bonding-pad reverse surface, surrounded by the bonding-pad reverse surface as viewed in the thickness direction, and including a part present at a position different from the bonding-pad reverse surface in the thickness direction.

Clause 2.

The semiconductor device according to clause 1, wherein the first wire includes a bonding portion bonded to the bonding-pad obverse surface, and
at least a part of the bonding portion and at least a part of the first portion overlap with each other as viewed in the thickness direction.

Clause 3.

The semiconductor device according to clause 2, wherein the bonding portion is a second bonding portion.

Clause 4.

The semiconductor device according to any one of clauses 1 to 3, wherein the first portion is a recess including an opening edge in the bonding-pad reverse surface.

Clause 5.

The semiconductor device according to clause 4, wherein portions of the recess other than the opening edge are located inward from the opening edge as viewed in the thickness direction.

Clause 6.

The semiconductor device according to clause 5, wherein the recess includes a first surface inclined to become farther away from the bonding-pad reverse surface as viewed in the thickness direction as proceeding farther away from the bonding-pad reverse surface in the thickness direction.

Clause 7.

The semiconductor device according to clause 6, wherein a first angle formed between the first surface and a plane orthogonal to the thickness direction is equal to or greater than 25° and equal to or less than 50°.

Clause 8.

The semiconductor device according to clause 6 or 7, wherein the first surface has a shape of a loop as viewed in the thickness direction.

Clause 9.

The semiconductor device according to clause 6 or 7, wherein the recess includes a second surface inclined to become farther away from the bonding-pad reverse surface as viewed in the thickness direction as proceeding farther away from the bonding-pad reverse surface in the thickness direction and disposed at a position different from the first surface as viewed in the thickness direction.

Clause 10.

The semiconductor device according to any one of clauses 1 to 3, wherein the first portion is a protrusion that protrudes from the bonding-pad reverse surface.

Clause 11.

The semiconductor device according to any one of clauses 1 to 10, further comprising a sealing resin covering the semiconductor element, the first wire, and a part of each of the first lead and the second lead.

Clause 12.

The semiconductor device according to clause 11, wherein the first portion is covered with the sealing resin.

Clause 13.

The semiconductor device according to clause 12, wherein the second lead includes a terminal portion exposed from the sealing resin and offset from the bonding pad portion toward a side which the bonding-pad reverse surface faces in the thickness direction.

Clause 14.

The semiconductor device according to clause 13, wherein at least a part of the terminal portion and at least a part of the die pad portion overlap with each other as viewed in a direction orthogonal to the thickness direction.

Clause 15.

The semiconductor device according to clause 14, wherein the second lead includes a connecting portion interposed between the bonding pad portion and the terminal portion and having a bent shape.

Clause 16.

A method for manufacturing a semiconductor device, the method comprising the steps of:
preparing a first lead including a die pad portion and a second lead including a bonding pad portion, the die pad portion including a die-pad obverse surface and a die-pad reverse surface facing away from each other in a thickness direction, the bonding pad portion including a bonding-pad obverse surface facing a same side as the die-pad obverse surface in the thickness direction and a bonding-pad reverse surface facing away from the bonding-pad obverse surface;
mounting a semiconductor element on the die-pad obverse surface, the semiconductor element including an element body containing a semiconductor and a first electrode disposed on the element body; and
bonding a first wire to the first electrode and the bonding-pad obverse surface, wherein
the bonding-pad reverse surface is offset from the die-pad reverse surface toward the die-pad obverse surface-side in the thickness direction,
the bonding pad portion includes a single first portion, the first portion being connected to the bonding-pad reverse surface, surrounded by the bonding-pad reverse surface as viewed in the thickness direction, and including a part present at a position different from the bonding-pad reverse surface in the thickness direction,
the step of bonding the first wire includes supporting the second lead by a support, and
the support includes a support surface configured to come in contact with the bonding-pad reverse surface and a second portion configured to engage with the first portion of the second lead.

Clause 17.

The method for manufacturing a semiconductor device according to clause 16, wherein the first portion is a recess including an opening edge in the bonding-pad reverse surface.

Clause 18.

The method for manufacturing a semiconductor device according to clause 17, wherein portions of the recess other than the opening edge are located inward from the opening edge as viewed in the thickness direction.

### REFERENCE NUMERALS

A1, A2: Semiconductor device 1: First lead
2: Second lead 3: Third lead 4: Semiconductor element
7: Covered portion 8: Sealing resin 9: Support
11: Die pad portion 12: Extension
21: Bonding pad portion 22: Terminal portion
23: Connecting portion 31: Bonding pad portion
32: Terminal portion 33: Connecting portion
40: Element body 40a: Element obverse surface
40b: Element reverse surface 48: Control section
49: Bonding material 51: First wire
52: Second wire 81: Resin obverse surface
82: Resin reverse surface 83: First resin side surface
84: Second resin side surface 90: Base surface
91: Support surface 92: Second portion
93: Support surface 94: Fourth portion
111: Die-pad obverse surface 112: Die-pad reverse surface
211: Bonding-pad obverse surface
212: Bonding-pad reverse surface
213: First portion 311: Bonding-pad obverse surface
312: Bonding-pad reverse surface 313: Third portion
401: First electrode 402: Second electrode
403: Third electrode 408: Functional layer
510: Wire material 511: Bonding portion
512: Bonding portion 513: Loop portion
521: Bonding portion 522: Bonding portion
523: Loop portion 921: First surface
925: Top surface 941: First surface
945: Top surface 2130: Opening edge
2131: First surface 2132: Second surface
2133: Third surface 2134: Fourth surface
2135: Bottom surface 3130: Opening edge
3131: First surface 3135: Bottom surface
Cp: Capillary α1, α2: Angle

1. A semiconductor device comprising:
a semiconductor element including an element body containing a semiconductor and a first electrode disposed on the element body;
a first lead on which the semiconductor element is mounted;
a second lead; and
a first wire electrically connecting the semiconductor element and the second lead, wherein
the first lead includes a die pad portion including a die-pad obverse surface and a die-pad reverse surface facing away from each other in a thickness direction,
the semiconductor element is mounted on the die-pad obverse surface,
the second lead includes a bonding pad portion including a bonding-pad obverse surface facing a same side as the die-pad obverse surface in the thickness direction and a bonding-pad reverse surface facing away from the bonding-pad obverse surface,
the bonding-pad reverse surface is offset from the die-pad reverse surface toward the die-pad obverse surface-side in the thickness direction,
the first wire is bonded to the first electrode and the bonding-pad obverse surface, and
the bonding pad portion includes a single first portion, the first portion being connected to the bonding-pad reverse surface, surrounded by the bonding-pad reverse surface as viewed in the thickness direction, and including a part present at a position different from the bonding-pad reverse surface in the thickness direction.

2. The semiconductor device according to claim 1, wherein the first wire includes a bonding portion bonded to the bonding-pad obverse surface, and
at least a part of the bonding portion and at least a part of the first portion overlap with each other as viewed in the thickness direction.

3. The semiconductor device according to claim 2, wherein the bonding portion is a second bonding portion.

4. The semiconductor device according to claim 1, wherein the first portion is a recess including an opening edge in the bonding-pad reverse surface.

5. The semiconductor device according to claim 4, wherein portions of the recess other than the opening edge are located inward from the opening edge as viewed in the thickness direction.

6. The semiconductor device according to claim 5, wherein the recess includes a first surface inclined to become farther away from the bonding-pad reverse surface as viewed in the thickness direction as proceeding farther away from the bonding-pad reverse surface in the thickness direction.

7. The semiconductor device according to claim 6, wherein a first angle formed between the first surface and a plane orthogonal to the thickness direction is equal to or greater than 25° and equal to or less than 50°.

8. The semiconductor device according to claim 6, wherein the first surface has a shape of a loop as viewed in the thickness direction.

9. The semiconductor device according to claim 6, wherein the recess includes a second surface inclined to become farther away from the bonding-pad reverse surface as viewed in the thickness direction as proceeding farther away from the bonding-pad reverse surface in the thickness direction and disposed at a position different from the first surface as viewed in the thickness direction.

10. The semiconductor device according to claim 1, wherein the first portion is a protrusion that protrudes from the bonding-pad reverse surface.

11. The semiconductor device according to claim 1, further comprising a sealing resin covering the semiconductor element, the first wire, and a part of each of the first lead and the second lead.

12. The semiconductor device according to claim 11, wherein the first portion is covered with the sealing resin.

13. The semiconductor device according to claim 12, wherein the second lead includes a terminal portion exposed from the sealing resin and offset from the bonding pad portion toward a side which the bonding-pad reverse surface faces in the thickness direction.

14. The semiconductor device according to claim 13, wherein at least a part of the terminal portion and at least a part of the die pad portion overlap with each other as viewed in a direction orthogonal to the thickness direction.

15. The semiconductor device according to claim 14, wherein the second lead includes a connecting portion interposed between the bonding pad portion and the terminal portion and having a bent shape.

16. A method for manufacturing a semiconductor device, the method comprising the steps of:
preparing a first lead including a die pad portion and a second lead including a bonding pad portion, the die pad portion including a die-pad obverse surface and a die-pad reverse surface facing away from each other in a thickness direction, the bonding pad portion including a bonding-pad obverse surface facing a same side as the die-pad obverse surface in the thickness direction and a bonding-pad reverse surface facing away from the bonding-pad obverse surface;
mounting a semiconductor element on the die-pad obverse surface, the semiconductor element including an element body containing a semiconductor and a first electrode disposed on the element body; and
bonding a first wire to the first electrode and the bonding-pad obverse surface, wherein
the bonding-pad reverse surface is offset from the die-pad reverse surface toward the die-pad obverse surface-side in the thickness direction,
the bonding pad portion includes a single first portion, the first portion being connected to the bonding-pad reverse surface, surrounded by the bonding-pad reverse surface as viewed in the thickness direction, and including a part present at a position different from the bonding-pad reverse surface in the thickness direction,
the step of bonding the first wire includes supporting the second lead by a support, and
the support includes a support surface configured to come in contact with the bonding-pad reverse surface and a second portion configured to engage with the first portion of the second lead.

17. The method for manufacturing a semiconductor device according to claim 16, wherein the first portion is a recess including an opening edge in the bonding-pad reverse surface.

18. The method for manufacturing a semiconductor device according to claim 17, wherein portions of the recess other than the opening edge are located inward from the opening edge as viewed in the thickness direction.
